(19) United States
(12) Patent Application Publication
(10) Pub. No.: US 2018/0233664 A1
(43) Pub. Date: Aug. 16, 2018

(54) MEMORY DEVICE

(71) Applicant: Toshiba Memory Corporation, Tokyo (JP)

(72) Inventor: Toshiyuki IWAMOTO, Mie Mie (JP)

(21) Appl. No.: 15/695,450

(22) Filed: Sep. 5, 2017

(30) Foreign Application Priority Data
Feb. 14, 2017 (JP) 2017-025259

(51) Int. Cl. H01L 45/00; H01L 27/24

(52) U.S. Cl. CPC H01L 45/08; H01L 27/2436; G11C 13/0069; H01L 27/2481; H01L 45/1253; H01L 45/1226

(57) ABSTRACT

A memory device includes a first interconnection, a second interconnection including a first material, and a variable resistance film between the first interconnection and the second interconnection The variable resistance film includes a first layer including a second material, a second layer between the first layer and the second interconnection and including a third material, a third layer between the first layer and the second layer and including a fourth material, and a fourth layer between the second layer and the second interconnection and including a fifth material. A reactivity of the fourth material with the second material is less than a reactivity of the third material and the second material, and a reactivity of the fifth material with the first material is less than a reactivity of the third material with the first material.

### CROSS-REFERENCE TO RELATED APPLICATION

This application is based upon and claims the benefit of priority from Japanese Patent Application No. 2017-025259, filed Feb. 14, 2017, the entire contents of which are incorporated herein by reference.

### FIELD

Embodiments described herein relate generally to a memory device.

### BACKGROUND

In an existing memory device, a variable resistance film is connected between two interconnects that extend in directions orthogonal to each other. It is possible to three-dimensionally stack two-terminal type memory cells and achieve a higher storage capacity. The high reliability of memory cells is desirable in a memory device of this type.

### BRIEF DESCRIPTION OF THE DRAWINGS

FIG. 1 is a perspective view of a memory device according to a first embodiment.

FIG. 2 is a cross-sectional view of memory cells of a memory device according to the first embodiment.

FIG. 3 shows a band structure of the memory cell of a memory device according to the first embodiment.

FIG. 4 is a cross-sectional view of memory cells of a memory device according to a second embodiment.

FIG. 5 is a cross-sectional view of memory cells of a memory device according to a third embodiment.

FIG. 6 is a cross-sectional view of memory cells of a memory device according to a fourth embodiment.

FIG. 7 is a cross-sectional view of memory cells of a memory device according to a fifth embodiment.

### DETAILED DESCRIPTION

In general, according to one embodiment, a memory device includes a first interconnection, for example a bit line, extending in a first direction, a second interconnection, for example a word line, extending in a second direction intersecting the first direction, the second interconnection including a first material, and a first variable resistance film between the first interconnection and the second interconnection. The first variable resistance film includes a first layer, for example a resistance switching layer, including a second material, a second layer, for example a barrier layer, between the first layer and the second interconnection and including a third material, a third layer, for example a diffusion prevention layer, between the first layer and the second layer and including a fourth material, and a fourth layer, for example another diffusion prevention layer, between the second layer and the second interconnection and including a fifth material. A reactivity of the fourth material with the second material is less than a reactivity of the third material and the second material, and a reactivity of the fifth material with the first material is less than a reactivity of the third material with the first material.

### First Embodiment

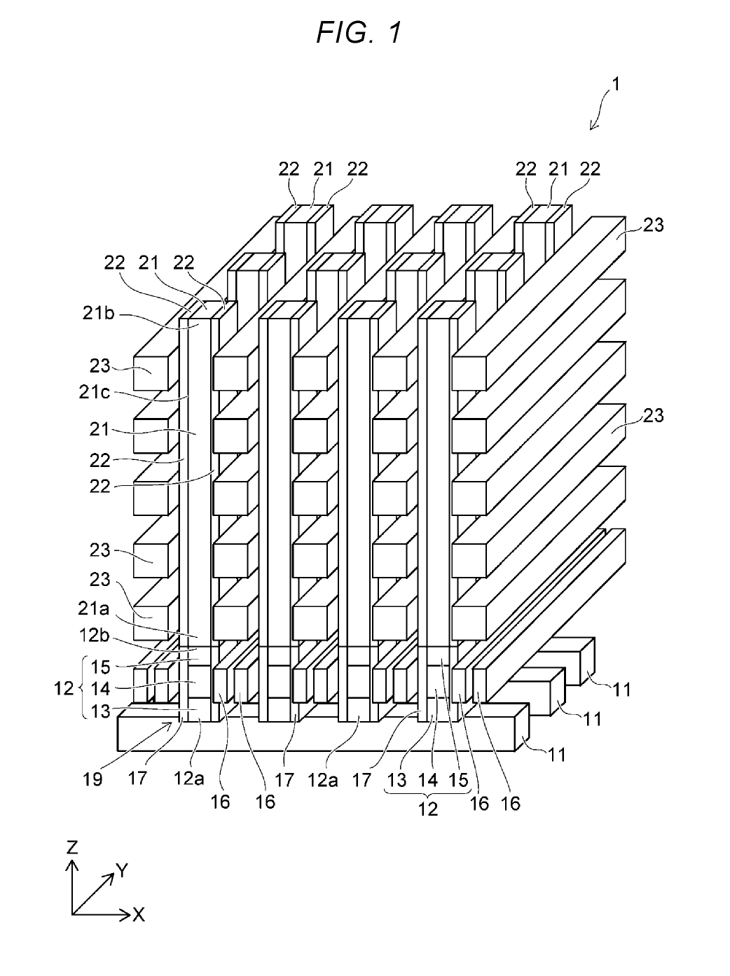

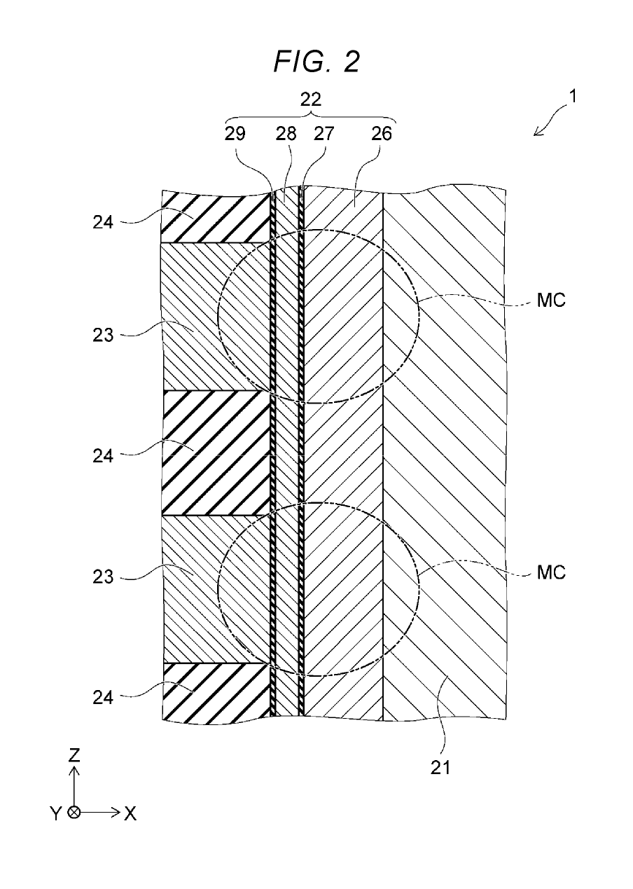

FIG. 1 is a perspective view of a memory device according to the first embodiment. FIG. 2 is a cross-sectional view of memory cells of a memory device according to the first embodiment.

As shown in FIG. 1, the memory device 1 according to the first embodiment includes a plurality of global bit lines 11. The global bit lines 11 are formed either by partitioning an upper layer portion of, for example, a silicon substrate (not shown) by an element isolation insulator (not shown) or by providing an insulating film (not shown) on the silicon substrate and depositing polysilicon on the insulating film.

Hereinafter, an arbitrary XYZ orthogonal coordinate system is adopted for explanatory convenience in the present specification. An “X direction” is defined as a direction in which the global bit lines 11 extend and a “Y direction” is defined as an array direction of the global bit lines 11. In addition, a “Z direction” is defined as a direction orthogonal to the X direction and the Y direction. While one of the Z directions is also referred to as “upward direction” and denoted by “+Z direction,” and the other direction is referred to as “downward direction” and denoted by “−Z direction,” the direction of gravity is irrelevant to definitions of the upward direction and the downward direction in this usage.

A plurality of silicon members 12 are provided on each global bit line 11. In a view from the Z direction, the silicon members 12 are arranged in a matrix configuration along the X direction and the Y direction. Each silicon member 12 is a quadrangular pyramid trapezoidal shape extending in the Z direction, and having an upper surface and a lower surface that are rectangles with sides thereof extending in the X direction and the Y direction, while the upper surface is smaller than the lower surface. Lower ends 12a of the plurality of silicon members 12 arranged in a line along the X direction are connected in common to one global bit line 11.

In each silicon member 12, from a global bit line 11 side in the upward direction, an n⁺ section 13, a p⁻ section 14, and an n⁺ section 15 are arranged in this order along the Z direction. In some embodiments, the n type and the p type may be reversed.

Two gate electrodes 16 extending in the Y direction are provided between the silicon members 12 in the X direction. The gate electrodes 16 are formed from, for example, titanium nitride (TiN). The gate electrodes 16 may instead be formed from polysilicon. In a view from the X direction, each gate electrode 16 overlaps an upper portion of the n⁺ section 13, an entirety of the p⁻ section 14, and a lower portion of the n⁺ section 15.

A gate insulating film 17 formed from, for example, silicon oxide, is provided between the silicon member 12 and the gate electrodes 16. The silicon member 12 including the n⁺ section 13, the p⁻ section 14, and the n⁺ section 15, the gate insulating films 17, and a pair of gate electrodes 16 sandwiching the silicon member 12 therebetween constitute a thin-film transistor (TFT) 19 of an n-channel type. The TFT 19 is a switching device that switches between conducting (passing) and cutting off (blocking) electrical current.

A local bit line 21 formed from, for example, titanium nitride (TiN) is provided on each silicon member 12. The local bit line 21 extends in the Z direction and for example, a quadrangular prism shaped. That the local bit line 21 extends in the Z direction, and a length of the local bit line 21 in the Z direction is larger than a width thereof in the X direction and a length thereof in the Y direction.

A lower end 21a of the local bit line 21 is connected to an upper end 12b of each silicon member 12. Since each local bit line 21 is disposed in a region right on each silicon member 12, a plurality of local bit lines 21 are arranged in a matrix configuration along the X direction and the Y direction in the memory device 1 as a whole.

A variable resistance film 22 is provided on each of two side surfaces 21c of the local bit line 21 oriented in the X direction. The variable resistance film 22 is a film having a resistance state that changes depending on a supplied voltage or current. The variable resistance films 22 each extend along one local bit line 21 in the Z direction from lower end 21a to upper end 21b of the local bit lines 21.

A plurality of word lines 23 extending in the Y direction are provided between the local bit lines 21 adjacent in the X direction, and are arranged so as to be isolated from one another in the Z direction. In a view from the Y direction, the word lines 23 are arranged in a matrix configuration along the X direction and the Z direction. The word lines 23 are formed from, for example, titanium nitride (TiN). The variable resistance film 22 is connected between one local bit line 21 and a plurality of word lines 23 arranged along the Z direction.

As shown in FIG. 2, a memory cell MC is configured in each intersecting portion between the local bit line 21 and each word line 23 via the variable resistance film 22. The memory cells MC are arranged in a three-dimensional matrix configuration along the X direction, the Y direction, and the Z direction. In FIG. 2, for the sake of convenience of description, the variable resistance film 22 is depicted somewhat thick as compared with the other constituent elements.

An interlayer insulating film 24 formed from, for example, silicon oxide (SiO) is provided in a space between the word lines 23 adjacent in the Z direction. The word lines 23 and the interlayer insulating films 24 are thereby arranged alternately along the Z direction.

The variable resistance films 22 are BMC (Band Modulated Conductive Cell) films. In each variable resistance film 22, a switching layer 26, a diffusion preventing layer 27, a barrier layer 28, and a diffusion preventing layer 29 are stacked in this order from a local bit line 21-side to a word line 23-side. That is, the switching layer 26 adjoins the local bit line 21 and the diffusion preventing layer 29 adjoins the word lines 23.

The switching layer 26 contains titanium (Ti) and oxygen (O) and is formed, for example, by a titanium oxide (TiO₂). Although examples of a chemical formula for each substance in the present disclosure, a compositional ratio in the substance is not limited to those examples. For example, a ratio of the number of titanium atoms to the number of oxygen atoms in titanium oxide that forms the switching layer 26 is not limited to (1:2) but may be, for example, (1:1.8). A dimension of the switching layer 26 e.g., a length/thickness thereof in the X direction is 5 to 10 nanometers (nm). The switching layer 26 includes a vacancy, also referred to as a point defect, and oxygen ions (O₂⁻) can migrate within the switching layer 26. As a result, the switching layer 26 shows a pseudo n-semiconductor type behavior and is thus conductive to a certain degree.

The diffusion preventing layers 27 and 29 are formed from an insulating material such as a metal oxide or a silicon nitride (Si₃N₄). Examples of a metal oxide that can be used in the diffusion preventing layers 27 and 29 include an aluminum oxide (Al₂O₃), a hafnium oxide (HfO₂), a zirconium oxide (ZrO₂), or a lanthanum oxide (La₂O₃). The reactivity of the material forming the diffusion preventing layer 27 towards titanium is lower than the reactivity of the material forming the barrier layer 28 towards titanium. Also, the reactivity of the material forming the diffusion preventing layer 29 towards the metal in the word lines 23 (e.g., titanium) is less than the reactivity of the material forming the barrier layer 28 towards the metal in the word lines 23. The diffusion preventing layers 27 and 29 are formed from an aluminum oxide, for example.

The diffusion preventing layers 27 and 29 are thinner than the switching layer 26 and the barrier layer 28. A thickness of each of the diffusion preventing layers 27 and 29 is, for example, equal to or smaller than 1 nm, and more specifically, for example, 0.3 to 0.5 nm.

The barrier layer 28 may be formed of undoped amorphous silicon (a-Si). A resistivity of the barrier layer 28 is higher than a resistivity of the switching layer 26. The barrier layer 28 is thinner than the switching layer 26. A thickness of the barrier layer 28 is, for example, 2 to 8 nm, and more specifically, for example, 3 nm.

Operations of the memory device 1 according to the first embodiment will next be described.

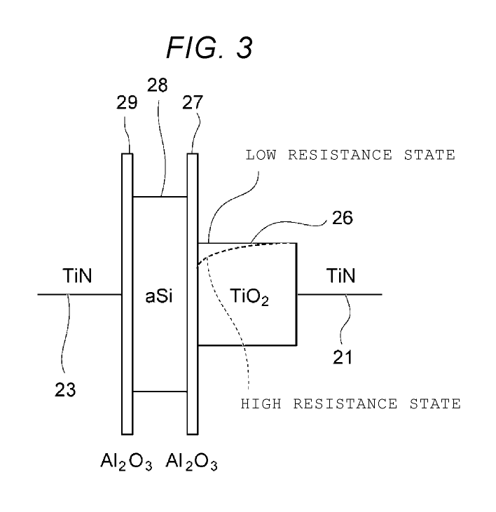

FIG. 3 depicts a memory cell of the memory device according to the first embodiment and an apparent conducting band state of the switching layer 26 under different conditions.

FIG. 3 is shown as an example for illustrative purposes and the depicted device and materials are for example and not limitations.

During a memory set operation, a drive circuit (not shown) of the memory device 1 applies, for example, a ground potential (0V) to the selected global bit line 11. Furthermore, the drive circuit applies an on-potential to the selected gate electrode 16 to set one TFT 19 to a conduction state. The ground potential (0V) is thereby applied to the selected local bit line 21 via the TFT 19. The drive circuit applies a positive write potential to the selected word line 23. The memory cell MC is thereby in a “low resistance state”.

Without being a limitation, the device operation is considered to be approximately as follows. When a positive voltage is applied to the word line 23 of a certain memory cell MC and a ground potential is applied to the local bit line 21, which thus acts as a negative electrode, and the word line 23 acts as a positive electrode, the oxygen ions gather in the vicinity of the diffusion preventing layer 27 and vacancies decrease in the switching layer 26. As a result, in the “low resistance state” (FIG. 3), the band state of the portion of the switching layer adjacent/proximate to the diffusion preventing layer 27 approaches to the band state of an intrinsic titanium oxide and, thus electrical current becomes easier to flow.

During a reset operation, the drive circuit of the memory device 1 applies the positive write potential to the selected global bit line 11. Furthermore, the drive circuit applies the on-potential to the selected gate electrode 16 to set one TFT 19 to a conduction state. The positive write potential is thereby applied to the selected local bit line 21 via the TFT 19. The drive circuit applies a lower potential, for example, the ground potential (0V) to the selected word line 23. The memory cell MC is thereby in a “high resistance state”.

When a positive voltage is applied to the local bit line 21 of a certain memory cell MC and a ground potential is applied to the word line 23, that is the local bit line 21 acts as a positive electrode and the word line 23 acts as a negative electrode, the oxygen ions move away from the vicinity of the diffusion preventing layer 27 and vacancies increase in the switching layer 26. As a result, as indicated as a “high resistance state” in FIG. 3, the energy band state of the switching layer 26 in the vicinity of the diffusion preventing layer 27 deforms from the band state of intrinsic titanium oxide. That is, a difference in an energy level between the switching layer 26 and the diffusion preventing layer 27 increases, and thus electrical current is more difficult to flow.

In this way, in the memory device 1, oxygen ions are allowed to migrate within the switching layer 26 and a resistance of the variable resistance film 22 can be switched between the “low resistance state” and the “high resistance state” by applying a predetermined voltage between the local bit line 21 and the word line 23. As a result, it is possible to write data to the memory cell MC. Furthermore, by measuring a resistance of the variable resistance film 22 while electrical current flows in the variable resistance film 22, it is possible to read the data written to the memory cell MC.

The diffusion preventing layer 27 prevents diffusion of titanium from the switching layer 26 into the barrier layer 28 and diffusion of silicon from the barrier layer 28 into the switching layer 26. It is thereby possible to prevent formation of a titanium silicide by a reaction between titanium and silicon diffusants. Furthermore, by setting the thickness of the diffusion preventing layer 27 to be equal to or smaller than 1 nm, it is possible to avoid excessively increasing the resistance of the variable resistance film 22.

Moreover, the diffusion preventing layer 29 prevents diffusion of silicon from the barrier layer 28 into the word line 23 and also diffusion of titanium from the word line 23 into the barrier layer 28. It is thereby possible to prevent formation of a titanium silicide by a reaction between titanium and silicon diffusants. Furthermore, by setting the thickness of the diffusion preventing layer 29 to be equal to or smaller than 1 nm, it is possible to avoid excessively increasing the resistance of the variable resistance film 22.

Advantages of the first embodiment will next be described.

In the memory device 1 according to the first embodiment, the diffusion preventing layer 27 is provided between the switching layer 26 and the barrier layer 28. Thus, even when the electrical current flows through the variable resistance film 22 and Joule heat is generated in response to the memory setting operation, the reset operation or a read operation on the memory cell MC, the formation of titanium silicide by the reaction between titanium contained in the switching layer 26 and silicon contained in the barrier layer 28 is prevented. Therefore, it is possible to prevent generation of a short circuiting passage within the variable resistance film 22.

Furthermore, the diffusion preventing layer 29 is provided between the barrier layer 28 and the word line 23, whereby even when the electrical current flows through the variable resistance film 22 and the Joule heat is generated, the formation of titanium silicide by the reaction between silicon from the barrier layer 28 and titanium from the word line 23 is prevented. Therefore, it is possible to prevent the generation a short circuiting passage within the variable resistance film 22.

In this way, according to the first embodiment, by providing the diffusion preventing layers 27 and 29, it is possible to prevent the formation of titanium silicide within the variable resistance film 22 even when the electrical current flows repeatedly through the variable resistance film 22 in response to driving of the memory device 1. As a result, it is possible to maintain the reliability of the memory cells MC for a longer period of time.

In some embodiments, the word lines 23 may be formed from a metallic material, such as tungsten (W), other than titanium nitride. In this case, the diffusion preventing layer 29 prevents diffusion of the metal, such as tungsten, contained in the word line 23 into the barrier layer 28 and prevents formation of a metal silicide.

### Second Embodiment

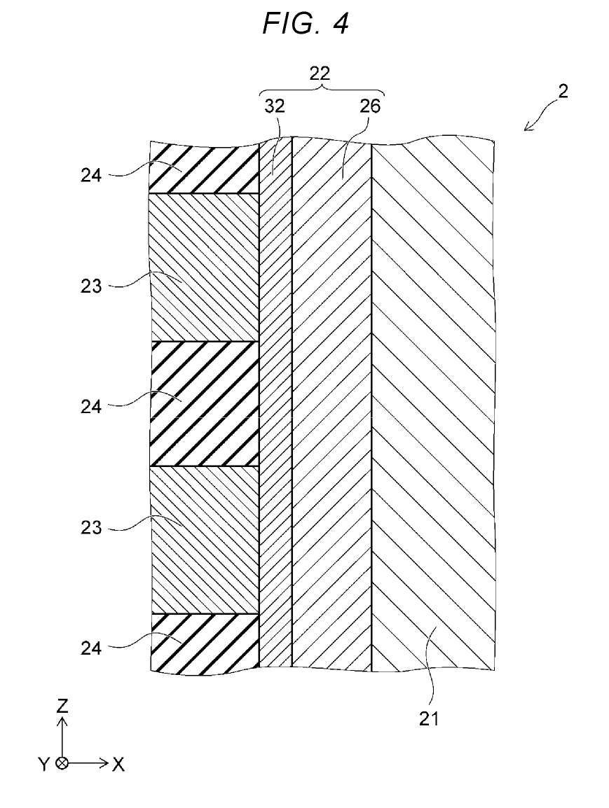

FIG. 4 is a cross-sectional view of memory cells of a memory device according to the second embodiment.

As shown in FIG. 4, a memory device 2 according to the second embodiment differs in a configuration of the variable resistance film 22 from the memory device 1 shown in FIG. 2 according to the first embodiment described above. That is, in the variable resistance film 22 of the memory device 2, a barrier layer 32 is provided as an alternative to the barrier layer 28 in FIG. 2, and the diffusion preventing layers 27 and 29 in FIG. 2 are not provided. The barrier layer 32 is disposed between the switching layer 26 and the word lines 23. A configuration of the switching layer 26 is substantially similar to that of the switching layer 26 according to the first embodiment.

The barrier layer 32 is formed from carbon-containing silicon (Si—C). A carbon concentration of the barrier layer 32 is, for example, 1 to 50 at % (atomic percentage). The carbon-containing silicon at the carbon concentration of 50 at % is a silicon carbide (SiC). A resistivity of the barrier layer 32 is higher than the resistivity of the switching layer 26. A thickness of the barrier layer 32 is, for example, 2 to 8 nm, and more specifically, for example, 3 nm.

In the memory device 2 according to the second embodiment, carbon atoms in the barrier layer 32 block migration of silicon atoms from the barrier layer 32. It is thereby possible to prevent diffusion of silicon from the barrier layer 32 into the switching layer 26 and into the word line 23 and also prevent diffusion of titanium from the switching layer 26 and the word line 23 into the barrier layer 32. As a result, it is possible to maintain the reliability of the memory cells MC for a longer period of time.

Configurations and operations of the second embodiment other than those described above are substantially similar to those of the first embodiment described above.

### Third Embodiment

A third embodiment will next be described.

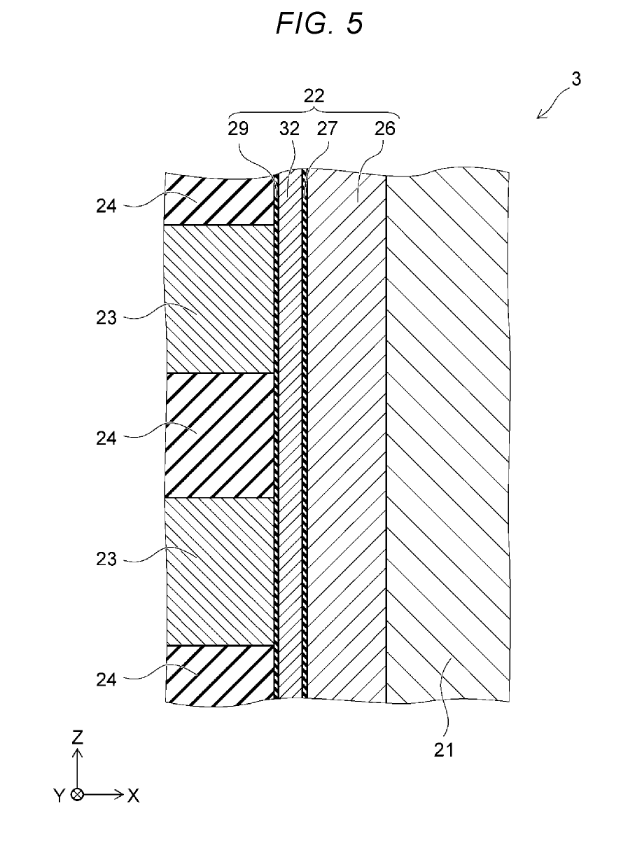

FIG. 5 is a cross-sectional view of memory cells of a memory device according to the third embodiment.

As shown in FIG. 5, the third embodiment is an example of a combination of the first embodiment and the second embodiment described above. That is, in a memory device 3 according to the third embodiment, the diffusion preventing layers 27 and 29 are provided in addition to the configurations of the memory device 2 shown in FIG. 4 according to the second embodiment described above.

According to the third embodiment, in a difference with the second embodiment, the diffusion preventing layers 27 and 29 are provided. It is therefore possible to more effectively prevent the diffusion of silicon from the barrier layer 32 into the switching layer 26 and into the word line 23 and also the diffusion of titanium from the switching layer 26 and the word line 23 into the barrier layer 32. As a result, the reliability of the memory cells MC further improves.

Configurations, operations, and advantages of the third embodiment other than those described above are otherwise substantially similar to those of the second embodiment described above. In some embodiments, only one of the diffusion preventing layers 27 and 29 may be provided.

### Fourth Embodiment

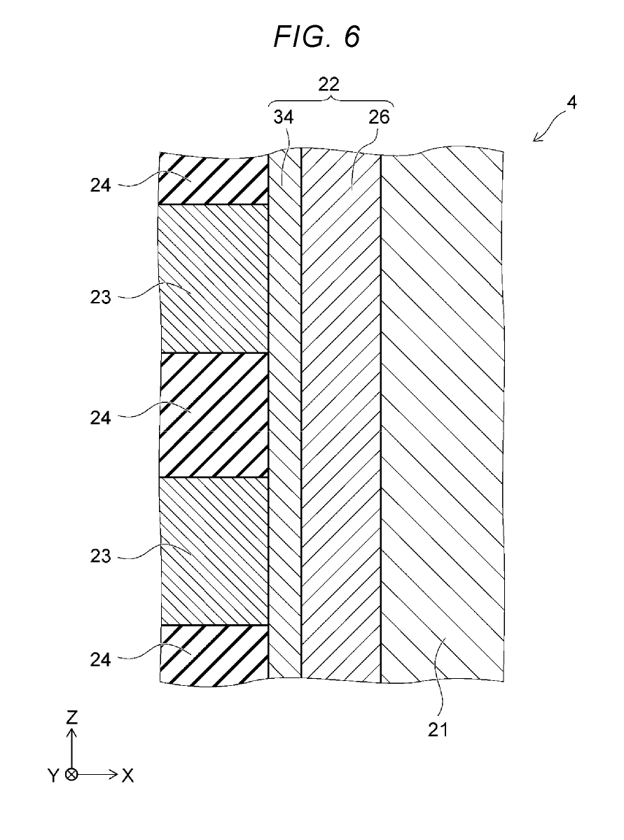

FIG. 6 is a cross-sectional view of memory cells of a memory device according to the fourth embodiment.

As shown in FIG. 6, a memory device 4 according to the fourth embodiment differs in the configuration of the variable resistance film 22 in the memory device 1 shown in FIG. 2 according to the first embodiment described above. That is, in the variable resistance film 22 of the memory device 4, a barrier layer 34 is provided as an alternative to the barrier layer 28 in FIG. 2, and the diffusion preventing layers 27 and 29 in FIG. 2 are not provided. The barrier layer 34 is disposed between the switching layer 26 and the word lines 23.

The barrier layer 34 is formed from diamond. A resistivity of the barrier layer 34 is higher than the resistivity of the switching layer 26. A thickness of the barrier layer 34 is, for example, 2 to 8 nm, and more specifically, for example, 3 nm.

In the memory device 4 according to the fourth embodiment, the barrier layer 34 does not contain silicon, so that diffusion of silicon from the barrier layer 34 into the switching layer 26 and into the word line 23 cannot occur. Furthermore, titanium contained in the switching layer 26 and the word line 23 finds it difficult to diffuse into the barrier layer 34. It is thereby possible to maintain the reliability of the memory cells MC for a longer period of time.

Configurations and operations of the fourth embodiment other than those described above are substantially similar to those of the first embodiment described above.

### Fifth Embodiment

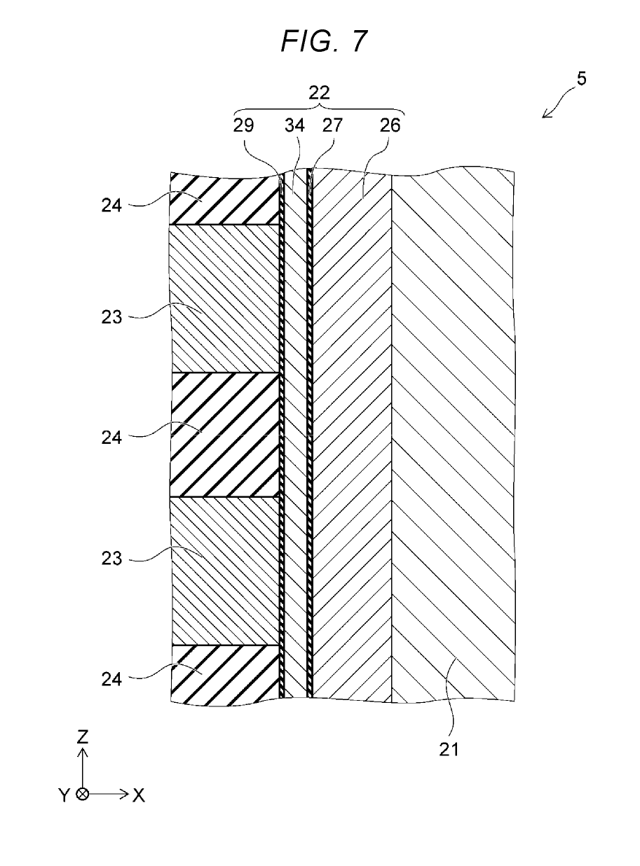

FIG. 7 is a cross-sectional view of memory cells of a memory device according to the fifth embodiment.

As shown in FIG. 7, the fifth embodiment is an example of a combination of the first embodiment and the fourth embodiment described above. That is, in a memory device 5 according to the fifth embodiment, the diffusion preventing layers 27 and 29 are provided in addition to the configurations of the memory device 4 in FIG. 6 according to the fourth embodiment described above.

According to the fifth embodiment, the diffusion preventing layers 27 and 29 are provided along with the aspects fourth embodiment. It is, therefore, possible to more effectively prevent the diffusion of carbon from the barrier layer 34 into the switching layer 26 and into the word line 23 and the diffusion of titanium from the switching layer 26 and the word line 23 into the barrier layer 34. The reliability of the memory cells MC thereby further improves.

Configurations, operations, and advantages of the fifth embodiment other than those described above are substantially similar to those of the fourth embodiment described above. In some embodiments, only one of the diffusion preventing layers 27 and 29 may be provided.

According to the example embodiments described herein, it is possible to realize the memory device that ensures the high reliability of the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. In addition, the aforementioned embodiments can be embodied in combination. The accompanying claims and their equivalents are intended to cover such forms or modifications as would fall within the scope and spirit of the inventions.

What is claimed is:

1. A memory device, comprising:
a first interconnection extending in a first direction;
a second interconnection extending in a second direction intersecting the first direction, the second interconnection including a first material; and
a first variable resistance film being provided between the first interconnection and the second interconnection, the first variable resistance film including:
a first layer including a second material,
a second layer between the first layer and the second interconnection, the second layer having a resistivity higher than a resistivity of the first layer and including a third material,
a third layer between the first layer and the second layer and including a fourth material; and
a fourth layer between the second layer and the second interconnection and including a fifth material, wherein
a reactivity of the fourth material with the second material is less than a reactivity of the third material with the second material, and
a reactivity of the fifth material with the first material is less than a reactivity of the third material with the first material.

2. The memory device according to claim 1, wherein
the first material is a metal,
the second material is titanium,
the third material is silicon, and
the first layer comprises a titanium oxide.

3. The memory device according to claim 2, wherein the third material is amorphous silicon.

4. The memory device according to claim 2, wherein the third material comprises silicon and carbon.

5. The memory device according to claim 1, wherein the third material is diamond.

6. The memory device according to claim 1, wherein
the fourth and the fifth material are each a metal selected from aluminum, hafnium, zirconium, and lanthanum, and
the third layer and the fourth layer are each a metal oxide.

7. The memory device according to claim 1, wherein
the second layer is thinner than the first layer in a third direction intersecting to the first and second directions, and
the third layer and the fourth layer are each thinner than the second layer in the third direction.

8. The memory device according to claim 1, further comprising:
a third interconnection extending in the second direction; and
a second variable resistance film between the first interconnection and the third interconnection, wherein
the second interconnection and the third interconnection are arranged along the first direction, and
the second variable resistance film has same structure as the first variable resistance film.

9. The memory device according to claim 8, further comprising:
a fourth interconnection extending in the first direction, and
a third variable resistance film between the fourth interconnection and the second interconnection, wherein
the first interconnection and the fourth interconnection are arranged along the second direction, and
the third variable resistance film has the same structure as the first variable resistance film.

10. A memory device, comprising:
a first interconnection extending in a first direction;
a second interconnection extending in a second direction intersecting the first direction, the second interconnection including a first material; and
a first variable resistance film between the first interconnection and the second interconnection, the first variable resistance film including:
a first layer including a second material; and
a second layer between the first layer and the second interconnection and including a third material.

11. The memory device according to claim 10, wherein
the first material is a metal,
the second material is titanium,
the third material comprises silicon and carbon,
the first layer comprises a titanium oxide, and
the second layer is thinner than the first layer in a third direction orthogonal to the first and second directions.

12. The memory device according to claim 10, wherein
the first variable resistance film further includes a first diffusion prevention layer that is between the first layer and the second layer and includes a fourth material, and
the first diffusion prevention layer is thinner than the second layer in the third direction.

13. The memory device according to claim 12, wherein
the fourth material is a metal selected from aluminum, hafnium, zirconium, and lanthanum, and
the first diffusion prevention layer is a metal oxide.

14. The memory device according to claim 10, further comprising:
a third interconnection extending in the second direction; and
a second variable resistance film between the first interconnection and the third interconnection, wherein
the second interconnection and the third interconnection are arranged along the first direction, and
the second variable resistance film has same structure as the first variable resistance film.

15. The memory device according to claim 14, further comprising:
a fourth interconnection extending in the first direction, and
a third variable resistance film between the fourth interconnection and the second interconnection, wherein
the first interconnection and the fourth interconnection are arranged along the second direction, and
the third variable resistance film has the same structure as the first variable resistance film.

16. A memory device, comprising:
a first interconnection extending in a first direction;
a second interconnection extending in a second direction intersecting the first direction, the second interconnection including a first material; and
a first variable resistance film between the first interconnection and the second interconnection, the first variable resistance film including:
a first layer including a second material; and
a second layer between the first layer and the second interconnection and including a third material.

17. The memory device according to claim 16, wherein
the first material is a metal,
the second material is titanium,
the third material is diamond,
the first layer comprises a titanium oxide and
the second is thinner than the first layer in a third direction orthogonal to the first and second directions.

18. The memory device according to claim 17, wherein the fourth material is a metal selected from aluminum, hafnium, zirconium, and lanthanum.

19. The memory device according to claim 16, further comprising:
a third interconnection extending in the second direction; and
a second variable resistance film between the first interconnection and the third interconnection, wherein
the second interconnection and the third interconnection are arranged along the first direction, and
the second variable resistance film has same structure as the first variable resistance film.

20. The memory device according to claim 19, further comprising:
a fourth interconnection extending in the first direction, and
a third variable resistance film between the fourth interconnection and the second interconnection, wherein
the first interconnection and the fourth interconnection are arranged along the second direction, and
the third variable resistance film has the same structure as the first variable resistance film.
